(19) United States
(12) Patent Application Publication
(10) Pub. No.: US 2008/0163814 A1
(43) Pub. Date: Jul. 10, 2008

(54) CRYSTAL GROWTH OF M-PLANE AND SEMIPOLAR PLANES OF (Al, In, Ga, B)N ON VARIOUS SUBSTRATES

(75) Inventors: Kwang Choong Kim, Seoul (KR); Mathew C. Schmidt, Santa Barbara, CA (US); Feng Wu, Goleta, CA (US); Asako Hirai, Santa Barbara, CA (US); Melvin B. McLaurin, Goleta, CA (US); Steven P. DenBaars, Goleta, CA (US); Shuji Nakamura, Santa Barbara, CA (US); James S. Speck, Goleta, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 11/954,172

(22) Filed: Dec. 11, 2007

Related U.S. Application Data
(60) Provisional application No. 60/869,701, filed on Dec. 12, 2006.

(51) Int. Cl. C30B 23/04

(52) U.S. Cl. 117/95

(57) ABSTRACT

A method of reducing threading dislocation densities in non-polar such as a- {11-20} plane and m-{1-100} plane or semi-polar such as {10-1n} plane III-Nitrides by employing lateral epitaxial overgrowth from sidewalls of etched template material through a patterned mask. The method includes depositing a patterned mask on a template material such as a non-polar or semi polar GaN template, etching the template material down to various depths through openings in the mask, and growing non-polar or semi-polar III-Nitride by coalescing laterally from the tops of the sidewalls before the vertically growing material from the trench bottoms reaches the tops of the sidewalls. The coalesced features grow through the openings of the mask, and grow laterally over the dielectric mask until a fully coalesced continuous film is achieved.

This application claims the benefit under 35 U.S.C. Section 119(e) of co-pending and commonly-assigned U.S. provisional patent application, Ser. No. 60/869,701, filed Dec. 12, 2006, entitled “CRYSTAL GROWTH OF M-PLANE AND SEMI-POLAR PLANES OF (Al, In, Ga, B)N ON VARIOUS SUBSTRATES,” by Kwang C. Kim et al., which application is incorporated by reference herein.

This application is related to the following co-pending and commonly-assigned applications:

U.S. Utility application Ser. No. 10/581,940, filed on Jun. 7, 2006, by Tetsuo Fujii, Yan Gao, Evelyn. L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-US-WO (2004-063), which application claims the benefit under 35 U.S.C Section 365(c) of PCT Application Ser. No. US2003/03921, filed on Dec. 9, 2003, by Tetsuo Fujii, Yan Gao, Evelyn L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-WO-01 (2004-063);

U.S. Utility application Ser. No. 11/054,271, filed on Feb. 9, 2005, by Rajat Sharma, P. Morgan Pattison, John F. Kaeding, and Shuji Nakamura, entitled “SEMICONDUCTOR LIGHT EMITTING DEVICE,” attorney's docket number 30794.112-US-01 (2004-208);

U.S. Utility application Ser. No. 11/175,761, filed on Jul. 6, 2005, by Akihiko Murai, Lee McCarthy, Umesh K. Mishra and Steven P. DenBaars, entitled “METHOD FOR WAFER BONDING (Al, In, Ga)N and Zn(S, Se) FOR OPTOELECTRONICS APPLICATIONS,” attorney's docket number 30794.116-US-U1 (2004-455), which application claims the benefit under 35 U.S.C Section 119(e) of U.S. Provisional Application Ser. No. 60/585,673, filed Jul. 6, 2004, by Akihiko Murai, Lee McCarthy, Umesh K. Mishra and Steven P. DenBaars, entitled “METHOD FOR WAFER BONDING (Al, In, Ga)N and Zn(S, Se) FOR OPTOELECTRONICS APPLICATIONS,” attorney's docket number 30794.116-US-P 1 (2004-455-1);

U.S. Utility application Ser. No. 11/697,457, filed Apr. 6, 2007, by, Benjamin A. Haskell, Melvin B. McLaurin, Steven P. DenBaars, James S. Speck, and Shuji Nakamura, entitled “GROWTH OF PLANAR REDUCED DISLOCATION DENSITY M-PLANE GALLIUM NITRIDE BY HYDRIDE VAPOR PHASE EPITAXY,” attorneys' docket number 30794.119-US-C1 (2004-636-3), which application is a continuation of U.S. Utility application Ser. No. 11/140,893, filed May 31, 2005, by, Benjamin A. Haskell, Melvin B. McLaurin, Steven P. DenBaars, James S. Speck, and Shuji Nakamura, entitled “GROWTH OF PLANAR REDUCED DISLOCATION DENSITY M-PLANE GALLIUM NITRIDE BY HYDRIDE VAPOR PHASE EPITAXY,” attorneys' docket number 30794.119-US-U1 (2004-636-2), now U.S. Pat. No. 7,208,393, issued Apr. 24, 2007, which application claims the benefit under 35 U.S.C. Section 119(e) of U.S. Provisional Application Ser. No. 60/576,685, filed Jun. 3, 2004, by Benjamin A. Haskell, Melvin B. McLaurin, Steven P. DenBaars, James S. Speck, and Shuji Nakamura, entitled “GROWTH OF PLANAR REDUCED DISLOCATION DENSITY M-PLANE GALLIUM NITRIDE BY HYDRIDE VAPOR PHASE EPITAXY,” attorneys' docket number 30794.119-US-P1 (2004-636-1);

U.S. Utility application Ser. No. 11/067,957, filed Feb. 28, 2005, by Claude C. A. Weisbuch, Aurelien J. F. David, James S. Speck and Steven P. DenBaars, entitled “HORIZONTAL EMITTING, VERITCAL EMITTING, BEAM SHAPED, DISTRIBUTED FEEDBACK (DFB) LASERS BY GROWTH OVER A PATTERNED SUBSTRATE,” attorneys' docket number 30794.121-US-01 (2005-144-1);

U.S. Utility application Ser. No. 11/923,414, filed Oct. 24, 2007, by Claude C. A. Weisbuch, Aurelien J. F. David, James S. Speck and Steven P. DenBaars, entitled “SINGLE OR MULTI-COLOR HIGH EFFICIENCY LIGHT EMITTING DIODE (LED) BY GROWTH OVER A PATTERNED SUBSTRATE,” attorneys' docket number 30794.122-US-C1 (2005-145-2), which application is a continuation of U.S. Pat. No. 7,291,864, issued Nov. 6, 2007, to Claude C. A. Weisbuch, Aurelien J. F. David, James S. Speck and Steven P. DenBaars, entitled “SINGLE OR MULTI-COLOR HIGH EFFICIENCY LIGHT EMITTING DIODE (LED) BY GROWTH OVER A PATTERNED SUBSTRATE,” attorneys' docket number 30794.122-US-01 (2005-145-1);

U.S. Utility application Ser. No. 11/067,956, filed Feb. 28, 2005, by Aurelien J. F. David, Claude C.A Weisbuch and Steven P. DenBaars, entitled “HIGH EFFICIENCY LIGHT EMITTING DIODE (LED) WITH OPTIMIZED PHOTONIC CRYSTAL EXTRACTOR,” attorneys' docket number 30794.126-US-01 (2005-198-1);

U.S. Utility application Ser. No. 11/621,482, filed Jan. 9, 2007, by Troy J. Baker, Benjamin A. Haskell, Paul T. Fini, Steven P. DenBaars, James S. Speck, and Shuji Nakamura, entitled “TECHNIQUE FOR THE GROWTH OF PLANAR SEMI-POLAR GALLIUM NITRIDE,” attorneys' docket number 30794.128-US-C1 (2005-471-3), which application is a continuation of U.S. Utility application Ser. No. 11/372,914, filed Mar. 10, 2006, by Troy J. Baker, Benjamin A. Haskell, Paul T. Fini, Steven P. DenBaars, James S. Speck, and Shuji Nakamura, entitled “TECHNIQUE FOR THE GROWTH OF PLANAR SEMI-POLAR GALLIUM NITRIDE,” attorneys' docket number 30794.128-US-U1 (2005-471-2), now U.S. Pat. No. 7,220,324, issued May 22, 2007, which application claims the benefit under 35 U.S.C. Section 119(e) of U.S. Provisional Application Ser. No. 60/660,283, filed Mar. 10, 2005, by Troy J. Baker, Benjamin A. Haskell, Paul T. Fini, Steven P. DenBaars, James S. Speck, and Shuji Nakamura, entitled “TECHNIQUE FOR THE GROWTH OF PLANAR SEMI-POLAR GALLIUM NITRIDE,” attorneys' docket number 30794.128 -US-P1 (2005-471-1);

U.S. Utility application Ser. No. 11/403,624, filed Apr. 13, 2006, by James S. Speck, Troy J. Baker and Benjamin A. Haskell, entitled “WAFER SEPARATION TECHNIQUE FOR THE FABRICATION OF FREE-STANDING (AL, IN, GA)N WAFERS,” attorneys' docket number 30794.131-US-U1 (2005-482-2), which application claims the benefit under 35 U.S.C Section 119(e) of U.S. Provisional Application Ser. No. 60/670,810, filed Apr. 13, 2005, by James S. Speck, Troy J. Baker and Benjamin A. Haskell, entitled “WAFER SEPARATION TECHNIQUE FOR THE FABRICATION OF FREE-STANDING (AL, IN, GA)N WAFERS,” attorneys' docket number 30794.131-US-P1 (2005-482-1);

U.S. Utility application Ser. No. 11/403,288, filed Apr. 13, 2006, by James S. Speck, Benjamin A. Haskell, P. Morgan Pattison and Troy J. Baker, entitled “ETCHING TECHNIQUE FOR THE FABRICATION OF THIN (AL, IN, GA)N LAYERS,” attorneys' docket number 30794.132-US-U1 (2005-509-2), which application claims the benefit under 35 U.S.C Section 119(e) of U.S. Provisional Application Ser. No. 60/670,790, filed Apr. 13, 2005, by James S. Speck, Benjamin A. Haskell, P. Morgan Pattison and Troy J. Baker, entitled “ETCHING TECHNIQUE FOR THE FABRICATION OF THIN (AL, IN, GA)N LAYERS,” attorneys' docket number 30794.132-US-P1 (2005-509-1);

U.S. Utility application Ser. No. 11/454,691, filed on Jun. 16, 2006, by Akihiko Murai, Christina Ye Chen, Daniel B. Thompson, Lee S. McCarthy, Steven P. DenBaars, Shuji Nakamura, and Umesh K. Mishra, entitled “(Al,Ga,In)N AND ZnO DIRECT WAFER BONDING STRUCTURE FOR OPTOELECTRONIC APPLICATIONS AND ITS FABRICATION METHOD,” attorneys' docket number 30794.134-US-U1 (2005-536-4), which application claims the benefit under 35 U.S.C Section 119(e) of U.S. Provisional Application Ser. No. 60/691,710, filed on Jun. 17, 2005, by Akihiko Murai, Christina Ye Chen, Lee S. McCarthy, Steven P. DenBaars, Shuji Nakamura, and Umesh K. Mishra, entitled “(Al, Ga, In)N AND ZnO DIRECT WAFER BONDING STRUCTURE FOR OPTOELECTRONIC APPLICATIONS, AND ITS FABRICATION METHOD,” attorneys' docket number 30794.134-US-P1 (2005-536-1), U.S. Provisional Application Ser. No. 60/732,319, filed on Nov. 1, 2005, by Akihiko Murai, Christina Ye Chen, Daniel B. Thompson, Lee S. McCarthy, Steven P. DenBaars, Shuji Nakamura, and Umesh K. Mishra, entitled “(Al, Ga, In)N AND ZnO DIRECT WAFER BONDED STRUCTURE FOR OPTOELECTRONIC APPLICATIONS, AND ITS FABRICATION METHOD,” attorneys' docket number 30794.134-US-P2 (2005-536-2), and U.S. Provisional Application Ser. No. 60/764,881, filed on Feb. 3, 2006, by Akihiko Murai, Christina Ye Chen, Daniel B. Thompson, Lee S. McCarthy, Steven P. DenBaars, Shuji Nakamura, and Umesh K. Mishra, entitled “(Al,Ga,In)N AND ZnO DIRECT WAFER BONDED STRUCTURE FOR OPTOELECTRONIC APPLICATIONS AND ITS FABRICATION METHOD,” attorneys' docket number 30794.134-US-P3 (2005-536-3);

U.S. Utility application Ser. No. 11/444,084, filed May 31, 2006, by Bilge M, Imer, James S. Speck, and Steven P. DenBaars, entitled “DEFECT REDUCTION OF NON-POLAR GALLIUM GALLIUM NITRIDE WITH SINGLE-STEP SIDEWALL LATERAL EPITAXIAL OVERGROWTH,” attorneys' docket number 30794.135-US-U1 (2005-565-2), which claims the benefit under 35 U.S.C. 119(e) of U.S. Provisional Application Ser. No. 60/685,952, filed on May 31, 2005, by Bilge M, Imer, James S. Speck, and Steven P. DenBaars, entitled “DEFECT REDUCTION OF NON-POLAR GALLIUM GALLIUM NITRIDE WITH SINGLE-STEP SIDEWALL LATERAL EPITAXIAL OVERGROWTH,” attorneys' docket number 30794.135-US-P1 (2005-565-1);

U.S. Utility application Ser. No. 11/870,115, filed Oct. 10, 2007, by Bilge M, Imer, James S. Speck, Steven P. DenBaars and Shuji Nakamura, entitled “GROWTH OF PLANAR NON-POLAR M-PLANE III-NITRIDE USING METALORGANIC CHEMICAL VAPOR DEPOSITION (MOCVD),” attorneys' docket number 30794.136-US-C1 (2005-566-3), which application is a continuation of U.S. Utility application Ser. No. 11/444,946, filed May 31, 2006, by Bilge M, Imer, James S. Speck, and Steven P. DenBaars, entitled “GROWTH OF PLANAR NON-POLAR {1-100} M-PLANE GALLIUM NITRIDE WITH METALORGANIC CHEMICAL VAPOR DEPOSITION (MOCVD),” attorneys' docket number 30794.136-US-U1 (2005-566-2), which claims the benefit under 35 U.S.C. 119(e) of U.S. Provisional Application Ser. No. 60/685,908, filed on May 31, 2005, by Bilge M, Imer, James S. Speck, and Steven P. DenBaars, entitled “GROWTH OF PLANAR NON-POLAR {1-100} M-PLANE GALLIUM NITRIDE WITH METALORGANIC CHEMICAL VAPOR DEPOSITION (MOCVD),” attorneys' docket number 30794.136-US-P1 (2005-566-1);

U.S. Utility application Ser. No. 11/444,946, filed Jun. 1, 2006, by Robert M. Farrell, Troy J. Baker, Arpan Chakraborty, Benjamin A. Haskell, P. Morgan Pattison, Rajat Sharma, Umesh K. Mishra, Steven P. DenBaars, James S. Speck, and Shuji Nakamura, entitled “TECHNIQUE FOR THE GROWTH AND FABRICATION OF SEMIPOLAR (Ga, Al, In, B)N THIN FILMS, HETEROSTRUCTURES, AND DEVICES,” attorneys' docket number 30794.140-US-U1 (2005-668-2), which claims the benefit under 35 U.S.C. 119(e) of U.S. Provisional Application Ser. No. 60/686,244, filed on Jun. 1, 2005, by Robert M. Farrell, Troy J. Baker, Arpan Chakraborty, Benjamin A. Haskell, P. Morgan Pattison, Rajat Sharma, Umesh K. Mishra, Steven P. DenBaars, James S. Speck, and Shuji Nakamura, entitled “TECHNIQUE FOR THE GROWTH AND FABRICATION OF SEMIPOLAR (Ga, Al, In, B)N THIN FILMS, HETEROSTRUCTURES, AND DEVICES,” attorneys' docket number 30794.140-US-P1 (2005-668-1);

U.S. Utility application Ser. No. 11/251,365 filed Oct. 14, 2005, by Frederic S. Diana, Aurelien J. F. David, Pierre M. Petroff, and Claude C. A. Weisbuch, entitled “PHOTONIC STRUCTURES FOR EFFICIENT LIGHT EXTRACTION AND CONVERSION IN MULTI-COLOR LIGHT EMITTING DEVICES,” attorneys' docket number 30794.142-US-01 (2005-534-1);

U.S. Utility application Ser. No. 11/633,148, filed Dec. 4, 2006, Claude C. A. Weisbuch and Shuji Nakamura, entitled “IMPROVED HORIZONTAL EMITTING, VERTICAL EMITTING, BEAM SHAPED, DISTRIBUTED FEEDBACK (DFB) LASERS FABRICATED BY GROWTH OVER A PATTERNED SUBSTRATE WITH MULTIPLE OVERGROWTH,” attorneys' docket number 30794.143-US-U1 (2005-721-2), which application claims the benefit under 35 U.S.C Section 119(e) of U.S. Provisional Application Ser. No. 60/741,935, filed Dec. 2, 2005, Claude C. A. Weisbuch and Shuji Nakamura, entitled “IMPROVED HORIZONTAL EMITTING, VERTICAL EMITTING, BEAM SHAPED, DFB LASERS FABRICATED BY GROWTH OVER PATTERNED SUBSTRATE WITH MULTIPLE OVERGROWTH,” attorneys' docket number 30794.143-US-P1 (2005-721-1);

U.S. Utility application Ser. No. 11/517,797, filed Sep. 8, 2006, by Michael Iza, Troy J. Baker, Benjamin A. Haskell, Steven P. DenBaars, and Shuji Nakamura, entitled “METHOD FOR ENHANCING GROWTH OF SEMIPOLAR (Al, In, Ga, B)N VIA METALORGANIC CHEMICAL VAPOR DEPOSITION,” attorneys' docket number 30794.144-US-U1 (2005-722-2), which claims the benefit under 35 U.S.C. 119(e) of U.S. Provisional Application Ser. No. 60/715,491, filed on Sep. 9, 2005, by Michael Iza, Troy J. Baker, Benjamin A. Haskell, Steven P. DenBaars, and Shuji Nakamura, entitled “METHOD FOR ENHANCING GROWTH OF SEMIPOLAR (Al, In, Ga, B)N VIA METALORGANIC CHEMICAL VAPOR DEPOSITION,” attorneys' docket number 30794.144-US-U1 (2005-722-1);

U.S. Utility application Ser. No. 11/593,268, filed on Nov. 6, 2006, by Steven P. DenBaars, Shuji Nakamura, Hisashi Masui, Natalie N. Fellows, and Akihiko Murai, entitled “HIGH LIGHT EXTRACTION EFFICIENCY LIGHT EMITTING DIODE (LED),” attorneys' docket number 30794.161-US-U1 (2006-271-2), which application claims the benefit under 35 U.S.C Section 119(e) of U.S. Provisional Application Ser. No. 60/734,040, filed on Nov. 4, 2005, by Steven P. DenBaars, Shuji Nakamura, Hisashi Masui, Natalie N. Fellows, and Akihiko Murai, entitled “HIGH LIGHT EXTRACTION EFFICIENCY LIGHT EMITTING DIODE (LED),” attorneys' docket number 30794.161-US-P1 (2006-271-1);

U.S. Utility application Ser. No. 11/608,439, filed on Dec. 8, 2006, by Steven P. DenBaars, Shuji Nakamura and James S. Speck, entitled “HIGH EFFICIENCY LIGHT EMITTING DIODE (LED),” attorneys' docket number 30794.164-US-U1 (2006-318-3), which application claims the benefit under 35 U.S.C Section 119(e) of U.S. Provisional Application Ser. No. 60/748,480, filed on Dec. 8, 2005, by Steven P. DenBaars, Shuji Nakamura and James S. Speck, entitled “HIGH EFFICIENCY LIGHT EMITTING DIODE (LED),” attorneys' docket number 30794.164-US-P1 (2006-318-1), and U.S. Provisional Application Ser. No. 60/764,975, filed on Feb. 3, 2006, by Steven P. DenBaars, Shuji Nakamura and James S. Speck, entitled “HIGH EFFICIENCY LIGHT EMITTING DIODE (LED),” attorneys' docket number 30794.164-US-P2 (2006-318-2);

U.S. Utility application Ser. No. 11/676,999, filed on Feb. 20, 2007, by Hong Zhong, John F. Kaeding, Rajat Sharma, James S. Speck, Steven P. DenBaars and Shuji Nakamura, entitled “METHOD FOR GROWTH OF SEMIPOLAR (Al,In,Ga,B)N OPTOELECTRONIC DEVICES,” attorneys' docket number 30794.173 -US-U1 (2006-422-2), which application claims the benefit under 35 U.S.C Section 119(e) of U.S. Provisional Application Ser. No. 60/774,467, filed on Feb. 17, 2006, by Hong Zhong, John F. Kaeding, Rajat Sharma, James S. Speck, Steven P. DenBaars and Shuji Nakamura, entitled “METHOD FOR GROWTH OF SEMIPOLAR (Al,In,Ga,B)N OPTOELECTRONIC DEVICES,” attorneys' docket number 30794.173-US-P1 (2006-422-1);

U.S. Utility Patent Application Ser. No. 11/840,057, filed on Aug. 16, 2007, by Michael Iza, Hitoshi Sato, Steven P. DenBaars, and Shuji Nakamura, entitled “METHOD FOR DEPOSITION OF MAGNESIUM DOPED (Al, In, Ga, B)N LAYERS,” attorney's docket number 30794.187-US-U1 (2006-678-2), which claims the benefit under 35 U.S.C. 119(e) of U.S. Provisional Patent Application Ser. No. 60/822,600, filed on Aug. 16, 2006, by Michael Iza, Hitoshi Sato, Steven P. DenBaars, and Shuji Nakamura, entitled “METHOD FOR DEPOSITION OF MAGNESIUM DOPED (Al, In, Ga, B)N LAYERS,” attorney's docket number 30794.187-US-P1 (2006-678-1);

U.S. Utility Patent Application Ser. No. 11/940,848, filed on Nov. 15, 2007, by Aurelien J. F. David, Claude C. A. Weisbuch and Steven P. DenBaars entitled “HIGH LIGHT EXTRACTION EFFICIENCY LIGHT EMITTING DIODE (LED) THROUGH MULTIPLE EXTRACTORS,” attorney's docket number 30794.191-US-U1 (2007-047-3), which application claims the benefit under 35 U.S.C Section 119(e) of U.S. Provisional Patent Application Ser. No. 60/866,014, filed on Nov. 15, 2006, by Aurelien J. F. David, Claude C. A. Weisbuch and Steven P. DenBaars entitled “HIGH LIGHT EXTRACTION EFFICIENCY LIGHT EMITTING DIODE (LED) THROUGH MULTIPLE EXTRACTORS,” attorney's docket number 30794.191-US-P1 (2007-047-1), and U.S. Provisional Patent Application Ser. No. 60/883,977, filed on Jan. 8, 2007, by Aurelien J. F. David, Claude C. A. Weisbuch and Steven P. DenBaars entitled “HIGH LIGHT EXTRACTION EFFICIENCY LIGHT EMITTING DIODE (LED) THROUGH MULTIPLE EXTRACTORS,” attorney's docket number 30794.191-US-P2 (2007-047-2);

U.S. Utility Patent Application Ser. No. 11/940,853, filed on Nov. 15, 2007, by Claude C. A. Weisbuch, James S. Speck and Steven P. DenBaars entitled “HIGH EFFICIENCY WHITE, SINGLE OR MULTI-COLOUR LIGHT EMITTING DIODES (LEDS) BY INDEX MATCHING STRUCTURES,” attorney's docket number 30794.196-US-U1 (2007-114-2), which application claims the benefit under 35 U.S.C Section 119(e) of U.S. Provisional Patent Application Ser. No. 60/866,026, filed on Nov. 15, 2006, by Claude C. A. Weisbuch, James S. Speck and Steven P. DenBaars entitled “HIGH EFFICIENCY WHITE, SINGLE OR MULTI-COLOUR LED BY INDEX MATCHING STRUCTURES,” attorney's docket number 30794.196-US-P1 (2007-114-1);

U.S. Utility Patent Application Ser. No. 11/940,866, filed on Nov. 15, 2007, by Aurelien J. F. David, Claude C. A. Weisbuch, Steven P. DenBaars and Stacia Keller, entitled “HIGH LIGHT EXTRACTION EFFICIENCY LIGHT EMITTING DIODE (LED) WITH EMITTERS WITHIN STRUCTURED MATERIALS,” attorney's docket number 30794.197-US-U1 (2007-113-2), which application claims the benefit under 35 U.S.C Section 119(e) of U.S. Provisional Patent Application Ser. No. 60/866,015, filed on Nov. 15, 2006, by Aurelien J. F. David, Claude C. A. Weisbuch, Steven P. DenBaars and Stacia Keller, entitled “HIGH LIGHT EXTRACTION EFFICIENCY LED WITH EMITTERS WITHIN STRUCTURED MATERIALS,” attorney's docket number 30794.197-US-P1 (2007-113-1);

U.S. Utility Patent Application Ser. No. 11/940,876, filed on Nov. 15, 2007, by Evelyn L. Hu, Shuji Nakamura, Yong Seok Choi, Rajat Sharma and Chiou-Fu Wang, entitled “ION BEAM TREATMENT FOR THE STRUCTURAL INTEGRITY OF AIR-GAP III-NITRIDE DEVICES PRODUCED BY PHOTOELECTROCHEMICAL (PEC) ETCHING,” attorney's docket number 30794.201-US-U1 (2007-161-2), which application claims the benefit under 35 U.S.C Section 119(e) of U.S. Provisional Patent Application Ser. No. 60/866,027, filed on Nov. 15, 2006, by Evelyn L. Hu, Shuji Nakamura, Yong Seok Choi, Rajat Sharma and Chiou-Fu Wang, entitled “ION BEAM TREATMENT FOR THE STRUCTURAL INTEGRITY OF AIR-GAP III-NITRIDE DEVICES PRODUCED BY PHOTOELECTROCHEMICAL (PEC) ETCHING,” attorney's docket number 30794.201-US-P1 (2007-161-1);

U.S. Utility Patent Application Ser. No. 11/940,885, filed on Nov. 15, 2007, by Natalie N. Fellows, Steven P. DenBaars and Shuji Nakamura, entitled “TEXTURED PHOSPHOR CONVERSION LAYER LIGHT EMITTING DIODE,” attorney's docket number 30794.203-US-U1 (2007-270-2), which application claims the benefit under 35 U.S.C Section 119(e) of U.S. Provisional Patent Application Ser. No. 60/866,024, filed on Nov. 15, 2006, by Natalie N. Fellows, Steven P. DenBaars and Shuji Nakamura, entitled “TEXTURED PHOSPHOR CONVERSION LAYER LIGHT EMITTING DIODE,” attorney's docket number 30794.203-US-P1 (2007-270-1);

U.S. Utility Patent Application Ser. No. 11/940,872, filed on Nov. 15, 2007, by Steven P. DenBaars, Shuji Nakamura and Hisashi Masui, entitled “HIGH LIGHT EXTRACTION EFFICIENCY SPHERE LED,” attorney's docket number 30794.204-US-U1 (2007-271-2), which application claims the benefit under 35 U.S.C Section 119(e) of U.S. Provisional Patent Application Ser. No. 60/866,025, filed on Nov. 15, 2006, by Steven P. DenBaars, Shuji Nakamura and Hisashi Masui, entitled “HIGH LIGHT EXTRACTION EFFICIENCY SPHERE LED,” attorney's docket number 30794.204-US-P1 (2007-271-1);

U.S. Utility Patent Application Ser. No. 11/940,883, filed on Nov. 15, 2007, by Shuji Nakamura and Steven P. DenBaars, entitled “STANDING TRANSPARENT MIRRORLESS LIGHT EMITTING DIODE,” attorney's docket number 30794.205-US-U1 (2007-272-2), which application claims the benefit under 35 U.S.C Section 119(e) of U.S. Provisional Patent Application Ser. No. 60/866,017, filed on Nov. 15, 2006, by Shuji Nakamura and Steven P. DenBaars, entitled “STANDING TRANSPARENT MIRROR-LESS (STML) LIGHT EMITTING DIODE,” attorney's docket number 30794.205-US-P1 (2007-272-1); and

U.S. Utility Patent Application Ser. No. 11/940,898, filed on Nov. 15, 2007, by Steven P. DenBaars, Shuji Nakamura and James S. Speck, entitled “TRANSPARENT MIRRORLESS LIGHT EMITTING DIODE,” attorney's docket number 30794.206-US-U1 (2007-273-2), which application claims the benefit under 35 U.S.C Section 119(e) of U.S. Provisional Patent Application Ser. No. 60/866,023, filed on Nov. 15, 2006, by Steven P. DenBaars, Shuji Nakamura and James S. Speck, entitled “TRANSPARENT MIRROR-LESS (TML) LIGHT EMITTING DIODE,” attorney's docket number 30794.206-US-P1 (2007-273-1);

U.S. Utility patent application Ser. No. xx/xxx,xxx, filed on Dec. 11, 2007, by Steven P. DenBaars and Shuji Nakamura, entitled “LEAD FRAME FOR TRANSPARENT MIRRORLESS LIGHT EMITTING DIODE,” attorney's docket number 30794.210-US-U1 (2007-281-2), which claims the benefit under 35 U.S.C. 119(e) of U.S. Provisional Patent Application Ser. No. 60/869,454, filed on Dec. 11, 2006, by Steven P. DenBaars and Shuji Nakamura, entitled “LEAD FRAME FOR TM-LED,” attorney's docket number 30794.210-US-P1 (2007-281-1);

U.S. Utility patent application Ser. No. xx/xxx,xxx, filed on Dec. 11, 2007, by Shuji Nakamura, Steven P. DenBaars, and Hirokuni Asamizu, entitled, “TRANSPARENT LIGHT EMITTING DIODES,” attorney's docket number 30794.21 1-US-U1 (2007-282-2), which claims the benefit under 35 U.S.C. 119(e) of U.S. Provisional Patent Application Ser. No. 60/869,447, filed on Dec. 11, 2006, by Shuji Nakamura, Steven P. DenBaars, and Hirokuni Asamizu, entitled, “TRANSPARENT LEDS,” attorney's docket number 30794.211-US-P1 (2007-282-1);

U.S. Utility patent application Ser. No. xx/xxx,xxx, filed on Dec. 11, 2007, by Mathew C. Schmidt, Kwang Choong Kim, Hitoshi Sato, Steven P. DenBaars, James S. Speck, and Shuji Nakamura, entitled “METALORGANIC CHEMICAL VAPOR DEPOSITION (MOCVD) GROWTH OF HIGH PERFORMANCE NON-POLAR III-NITRIDE OPTICAL DEVICES,” attorney's docket number 30794.212-US-U1 (2007-316-2), which claims the benefit under 35 U.S.C. 119(e) of U.S. Provisional Patent Application Ser. No. 60/869,535, filed on Dec. 11, 2006, by Mathew C. Schmidt, Kwang Choong Kim, Hitoshi Sato, Steven P. DenBaars, James S. Speck, and Shuji Nakamura, entitled “MOCVD GROWTH OF HIGH PERFORMANCE M-PLANE GAN OPTICAL DEVICES,” attorney's docket number 30794.212-US-P1 (2007-316-1);

U.S. Utility patent application Ser. No. xx/xxx,xxx, filed on Dec. 11, 2007, by Steven P. DenBaars, Mathew C. Schmidt, Kwang Choong Kim, James S. Speck, and Shuji Nakamura, entitled, “NON-POLAR AND SEMI-POLAR EMITTING DEVICES,” attorney's docket number 30794.213-US-U1 (2007-317-2), which claims the benefit under 35 U.S.C. 119(e) of U.S. Provisional Patent Application Ser. No. 60/869,540, filed on Dec. 11, 2006, by Steven P. DenBaars, Mathew C. Schmidt, Kwang Choong Kim, James S. Speck, and Shuji Nakamura, entitled, “NON-POLAR (M-PLANE) AND SEMI-POLAR EMITTING DEVICES,” attorney's docket number 30794.213-US-P1 (2007-317-1);

U.S. Utility patent application Ser. No. xx/xxx,xxx, filed on Dec. 11, 2007, by Steven P. DenBaars, Mathew C. Schmidt, Kwang Choong Kim, James S. Speck, and Shuji Nakamura, entitled, “NON-POLAR AND SEMI-POLAR EMITTING DEVICES,” attorney's docket number 30794.213-US-U1 (2007-317-2), which claims the benefit under 35 U.S.C. 119(e) of U.S. Provisional Patent Application Ser. No. 60/869,540, filed on Dec. 11, 2006, by Steven P. DenBaars, Mathew C. Schmidt, Kwang Choong Kim, James S. Speck, and Shuji Nakamura, entitled, “NON-POLAR (M-PLANE) AND SEMI-POLAR EMITTING DEVICES,” attorney's docket number 30794.213-US-P1 (2007-317-1);

all of which applications are incorporated by reference herein.

### BACKGROUND OF THE INVENTION

1. Field of the Invention

The present invention relates to defect reduction of non-polar m-plane with sidewall lateral epitaxial overgrowth (LEO).

2. Description of the Related Art

In visible and ultraviolet high-power and high performance optoelectronic devices, c-plane Gallium nitride (GaN) is conventional because epitaxial growth techniques in the reactor including molecular beam epitaxy (MBE), metalorganic chemical vapor deposition (MOCVD), or hydride vapor phase epitaxy (HVPE) are easy.

However, this c-plane GaN has limitations due to the presence of polarization of polarization-induced electrostatic fields in the quantum wells. This large electronic polarization fields in the V-III nitride semiconductor within quantum well of optoelectric device affect to separation of electron and hole wavelength, and result in the quantum-confined stark effect. The consequences of this effect caused the reduced recombination efficiency and red-shifted emission with increasing forward current. Also external quantum efficiency decreases with further increase of the emission wavelength longer than 530 nm. To decrease internal field effects in the quantum wells grown along polar direction, nonpolar orientations such as a-plane (112-0) and m-plane(101-0) were suggested because these planes contain same number of Ga and N atoms, and have neutral charge. However, among nonpolar planes, a-plane GaN is relatively unstable to grow epitaxially, and shows little Indium incorporation rate, which are essential for high-power and high performance visible and ultraviolet optoelectronic devices. On the contrary, m-plane GaN shows stability during the growth, and Indium concentration rate within quantum wells is high enough for developing visible devices.

Another limitation is more critical to all planes GaN films using heteroepitaxy between GaN and substrates, i.e., growth on foreign substrates that have a lattice mismatch to GaN. Because of heteroepitaxy growth condition, defects such as dislocations and stacking faults are inevitable, and these defects can be non-radiative recombination centers and scattering centers causing low performance in the device structures. To decrease defects, lateral epitaxial overgrowth (LEO) or sidewall lateral epitaxial overgrowth (SLEO) technique using selective area growth was reported as very effective way among any other method. Basic idea for these is blocking dislocations from propagating parallel to the growth direction by using masking and changing growth direction.

The present invention minimizes defect density as well as polarization on non-polar m-plane GaN using SLEO. As a result, this structure shows defect reduced planar m-plane for high-performance optoelectronic devices.

### SUMMARY OF THE INVENTION

The present invention describes how to grow defect reduced non-polar m-plane GaN to promote lateral growth on sidewalls formed etching process using dielectric masking materials. On the substrate such as m-SiC, template was grown using a nucleation layer. Deposited dielectric materials on this template were patterned using photolithography, and etched down to substrates selectively to open windows. Lateral initiation on sidewall and diagonal regrowth (lateral and vertical) was followed by fast growth to get fully coalesced m-plane surface and additional surface smoothing growth.

Planar non-polar m-template grown heteroepitaxially contains dislocation densities of ˜10⁹ cm⁻² and stacking fault densities of ˜10⁵ cm⁻¹. By using this method, dislocation and stacking fault densities was reduced to 3×10⁸ cm⁻² and 4×10⁴ cm⁻¹. Also, stacking faults was localized on the edges of the window regions. The present invention also contains polarization-free advantage. Using non-polar m-plane GaN, radiative recombination rate and output power efficiency of devices are increased. In addition to these effects, polarized light emission is created, and can be useful on various applications, such as backing light unit or specialized lighting source.

The general purpose of the present invention is to create high quality (minimum defect density) non-polar a-{11-20} and m-{1-100} plane and semi-polar {10-1n} plane III-Nitride material by employing lateral overgrowth from sidewalls of etched nitride material through a dielectric mask. The method includes depositing a patterned mask on non-polar or semi-polar III-Nitride template, etching the template material down to various depths through openings in the mask, and regrowing the non-polar or semi-polar epitaxial film by coalescing laterally from the tops of the sidewalls before the vertically growing material from the trench bottoms reaches the surface. The coalesced features grow through the openings of the mask, and grow laterally over the dielectric mask until a fully coalesced continuous film is achieved.

These planar non-polar materials grown heteroepitaxially, such as a-GaN on top of r-A1₂O₃, contain dislocation densities of ˜10¹⁰ cm⁻² and stacking fault densities of 3.8×10⁵cm⁻¹ (aligned perpendicular to the c-axis) throughout the film. By using single step lateral epitaxial overgrowth, dislocation densities can be reduced down to ˜10⁷- 10⁹ cm⁻² and stacking faults are localized only on the nitrogen faces. With the present invention, using sidewall lateral epitaxial overgrowth, dislocation densities can be reduced down to even lower values by eliminating defects not only in the overgrown regions but also in the window regions. Also, by favoring gallium (Ga) face growth and limiting nitrogen (N) face growth stacking fault densities can be made orders of magnitude lower.

The present invention comprises methods and devices for reducing threading dislocation densities in a III-nitride material. Such a method comprises growing a nucleation layer on a substrate, growing a template layer on the nucleation layer, the template layer providing a crystal orientation, depositing a mask on the template layer, the mask having a top surface, etching the mask, the template layer, and the nucleation layer, wherein the crystal orientation is exposed on the template layer in a plurality of windows created by the etching, growing a group-III nitride layer within the plurality of windows, wherein when the growth of the group-III nitride layer reaches the top surface, the group-III nitride layer grows along the top surface such that growth within a first window coalesces with growth of a second window at an intersection point to create a substantially planar upper surface of the group-III nitride layer, and smoothing the substantially planar upper surface of the group-III nitride layer, such that the group-III nitride layer has a reduced number of threading dislocation densities.

Such a method further optionally comprises the substantially planar upper surface of the group-III nitride layer being in an m-plane,the group-III nitride layer being a non-polar material, the group-III nitride layer growing laterally along the top surface of the mask blocking the group-III nitride material growing vertically from the windows, the windows being aligned to create planar sidewalls in subsequent lateral growth steps, the template layer having a thickness scaled relative to a size of the windows to compensate for competing lateral to vertical growth rates, the etching being performed to one or more etch depths in order for the group-III nitride layer growing along the top surface to coalesce before the group-III nitride material growing within the windows completely reaches the tops of the sidewalls, changing a growth method of the group-III nitride layer after coalescence, the group-III nitride layer being grown in a temperature range of 1000-1250° C. and in a reactor pressure in a range of 20-760 Torr, the group-III nitride layer having a V/III ratio in a range of 100-3500 during different stages of the growth, and wherein a lateral growth rate is greater than a vertical growth rate, preventing growth from the bottoms of the trenches by depositing an additional mask on the bottoms of the trenches, and a device made by the method.

The present invention also takes advantage of the orientation of non-polar III-Nitrides to eliminate polarization fields. As a result, with the material produced by utilizing this invention, device improvements such as longer lifetimes, less leakage current, more efficient doping and higher output efficiency will be possible. In addition, a thick non-polar and semi-polar nitride free-standing substrate, which is needed to solve the lattice mismatch issue, can be produced over this material by various methods.

### BRIEF DESCRIPTION OF THE DRAWINGS

Referring now to the drawings in which like reference numbers represent corresponding parts throughout:

FIG. 1 is a flow chart, including schematics from template preparation to final SLEO regrowth.

FIGS. 2(a), 2(b), and 2(c) are scanning electron microscopy cross section image of SLEO from patterned SLEO template to fully coalesced SLEO.

FIG. 3(a) and 3(b) are atomic force microscopy images for a planar template 3(a) and a fully coalesced SLEO template 3(b).

FIG. 4(a), 4(b), 4(c), and 4(d) are transmission electron microscopy images. 4(a) is the cross section image of fully coalesced SLEO template, and 4(b) is enlarged from rectangular region in 4(a) for showing localized stacking faults. 4(c) and 4(d) plane-view images are for dislocation densities.

FIG. 5 is a table for x-ray diffraction full width half maximum values scanned on-axis for planar template and fully coalesced SLEO template.

FIGS. 6 is the Photoluminescence measurement result for planar template and fully coalesced SLEO template.

FIGS. 7(a) and 7(b) are the optical microscopy images for showing surface smoothing process. FIG. 7(a) is an example for a rough surface right after coalescence is done by MOCVD or HVPE. FIG. 7(b) is for after surface smoothing is done.

### DETAILED DESCRIPTION OF THE INVENTION

In the following description of the preferred embodiment, reference is made to the accompanying drawings that form a part hereof, and in which is shown by way of illustration a specific embodiment in which the invention may be practiced. It is to be understood that other embodiments may be utilized and structural changes may be made without departing from the scope of the present invention.

### Overview

Conventional growth technique of GaN materials has two problems because growth direction of GaN is polar c-direction, and uses heteroepitaxy, which causes higher defects density.

Growth GaN along c-direction is relatively easy; however, this [0001] c-direction cause lower performance in optical devices due to polarized fields causing electrons and holes charge separation in the active regions. To eliminate this effect, growth on non-polar plane is suggested. Between a-plane and m-plane, m-plane is promising, because m-plane has stronger stability and higher Indium incorporation rate during growth for visible and ultraviolet high power performance optical devices.

High defect density is the main reason for lower performance on both non-polar and polar GaN. Because m-plane bulk substrate with large area is not commercially available yet, foreign substrate such as m-plane SiC is necessary for growing non-polar m-plane GaN. This heteroepitaxial growth causes high defect densities due to lattice mismatch between substrate and m-plane GaN. These defect (dislocation and stacking fault) densities can be reduced significantly using dielectric masking materials and selective growth. Although simple lateral epitaxial overgrowth (LEO) is very effective to reduce defect densities on the wing regions, sidewalls lateral epitaxial overgrowth (SLEO) provides defect reduction overall area including window regions. The present invention shows simplified SLEO with the same amount of defect reduction as the conventional SLEO. Also this invention furthermore combines surface smoothing growth for making real device structures after coalescence.

The growth of (Ga, In, Al, B)N materials in the polar [0001] c-direction causes lower performance in optical devices due to polarization fields causing charge separation along the primary conduction direction. Therefore, research has recently been conducted on non-polar direction growth along the a-[11-20] and m-[1-100] directions of these materials to eliminate such effects and improve device performance significantly.

Another problem that is common to polar, semi-polar and non-polar III-Nitride materials is high defect densities, the most common of which are dislocations and stacking faults. Dislocations arise as a result of lattice mismatch in heteroepitaxial growth due to a lack of proper III-Nitride substrates, and stacking faults form because of disorder of atomic stacking during growth, which is, for example, predominant on the nitrogen face sidewall during a-plane GaN growth. With the present invention, the presence of these stacking faults can be minimized by favoring Ga face growth and limiting N face growth. Dislocation densities in directly grown (Ga, In, Al, B)N materials are quite high. High-performance devices could be achieved by reducing or ideally eliminating these defects accompanied by the use of non-polar materials. Such defects have been reduced by various methods involving LEO in polar and non-polar GaN over the years. The essence of these processes is to block or discourage dislocations from propagating perpendicular to the film surface by favoring lateral growth over vertical growth. Any LEO method involves blocking of defective material with the use of a mask deposited on the surface. Single-step LEO involves only one mask patterning and regrowth step, so it is simple to process and grow, but the results are not as effective as double-step LEO at defect reduction. Although double LEO is effective in defect reduction, it takes twice the amount of processing and growth efforts as compared to single step LEO, as the name implies. As a result, none of these methods have been both convenient and effective enough at the same time until now. With the use of SLEO in the present invention, it is possible to eliminate these defects in non-polar or semi-polar nitrides as effectively as double-step LEO by using as simple processing and growth methods as single-step LEO does. This invention nucleates on and grows from the tops of etched pillar sidewalls of non-polar or semi-polar nitride material, and coalesces the tops of the adjacent pillar sidewalls before the defective material from the heteroepitaxial interface (at the bottom of the trenches) reaches the top.

The present invention improves the materials' device performance in two ways: (1) by utilizing the natural structural advantage of non-polar material, a-{11-20} and m-{1-100} plane or semi-polar {10-1n} plane III-Nitride materials, to eliminate or reduce polarization effects, and (2) by eliminating defects effectively while employing a unique, reproducible, simple, and efficient process and growth method.

### Technical Description

The present invention reduces threading dislocation densities in non-polar m-plane and semi-polar nitrides by employing LEO from sidewalls of etched nitride material through a dielectric mask to promote the initiation and lateral epitaxial overgrowth on the sidewalls of etched GaN. As described earlier, stacking faults reside on the N face, one of the vertically oriented faces. This invention also decreases stacking fault densities with an anisotropy factor, i.e., by encouraging higher growth rates on the Ga-(0001) face and limiting the N-(000-1) face growth rates. By utilizing various growth conditions and processing methods, the present invention has demonstrated lateral growth and coalescence of non-polar GaN from sidewalls, and up and over the dielectric mask.

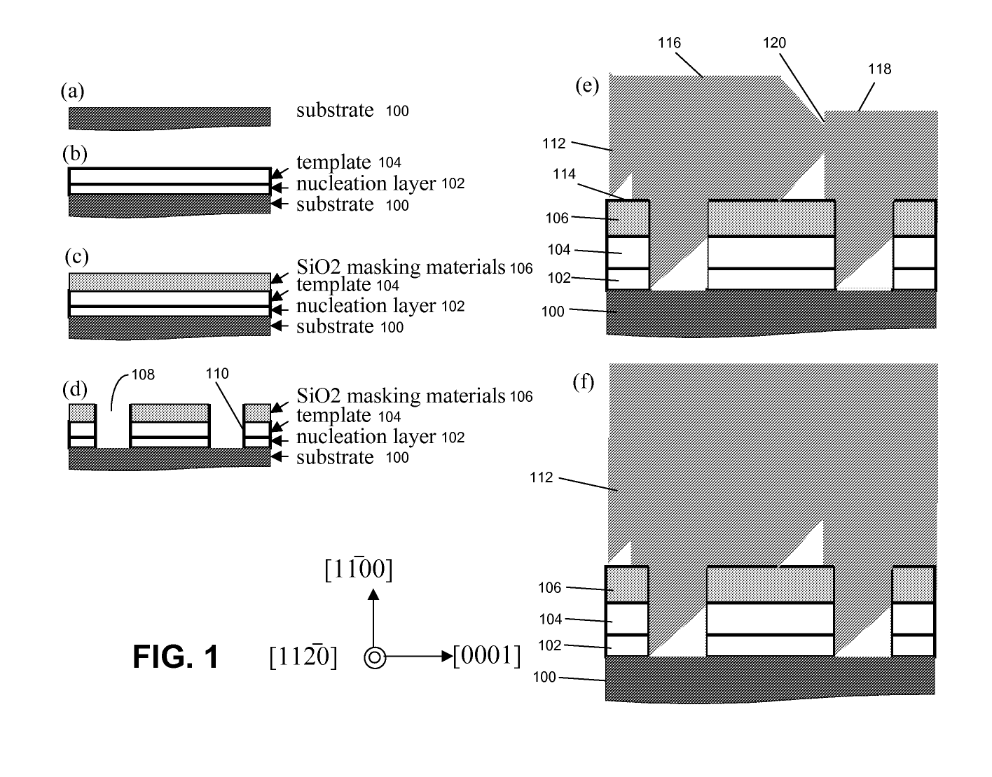

FIG. 1 is a flowchart that illustrates the steps for the growth of non-polar m-plane GaN using SLEO using MOCVD. There is, in essence, only a single growth step in the present invention, although it is described in several stages as shown herein below.

In step (a), substrate 100 is shown. Typically, substrate 100 is an m-SiC substrate, but other substrate materials can be used without departing from the scope of the present invention. In step (b), a nucleation layer 102 is grown on substrate 100. Typically, nucleation layer 102 is AlN, but can be other materials without departing from the scope of the present invention. A template layer 104, which is typically non-polar m-plane GaN, but can be other materials without departing from the scope of the present invention, is grown on the nucleation layer 102. The template layer 102 provides a crystal orientation for later growth steps.

In step (c), a dielectric mask 106 is deposited on template layer 104, typically using Plasma Enhanced Chemical Vapor Deposition (PECVD), although other methods of deposition can be used without departing from the scope of the present invention.

In step (d), layers 106, 104, and 102 are patterned and etched through a photolithography and etching process. To make window regions 108 and sidewalls 110 of GaN, the etching process should remove all materials in the opening including the dielectric mask 106, m-plane GaN template layer 104, and AlN nucleation layer 102. The sidewall 110 of GaN template layer 104 now has a crystal orientation that is desired for growth of new material.

In step (e), layer 112, which is typically non-polar m-plane GaN material, is grown in the window regions 108 and on sidewalls 110. As layer 112 starts to grow above the top surface 114 of dielectric mask 106, layer 112 starts growing laterally along top surface 114, until one lateral growth 116 meets up with another lateral growth 118 at a given intersection 120. At that point, layer 112 starts growing vertically. Intersections 120 is where each of the lateral growths coalesce with each other, and faster growth processes of layer 112 can be used. So for example, layer 112 initially is grown using MOCVD, and once the intersections 120 are coalesced, the growth of layer 112 can take place using HVPE.

The growth of layer 112 typically reaches the intersection 120 before the vertical growth from window regions 108 is completed, thus, the window region 108 will not be completely full of layer 112, and there may be voids underneath layer 112 along the top surface of mask 106. Further, window regions 108 can be selected in terms of size, depth, and distance between window regions 108 to control the growth of the layer 112 in the desired directions, both horizontally and vertically. For example, and not by way of limitation, some window regions 108 can be etched to different depths than other window regions 108, and some window regions 108 can be placed farther away from other window regions 108, to control the growth rates of layer 112 such that the lateral growth rate is faster than the vertical growth rate, or vice versa. Template layer 104 can also be sized, e.g., in terms of thickness, to compensate for the lateral v. vertical growth rates of layer 112.

Typically, the growth of layer 112 takes place in a temperature range of 1000-1250° C. and in a reactor pressure in a range of 20-760 Torr, and layer 112 has a V/III ratio in a range of 100-3500 during different stages of the growth. Additional mask layers 106 can also be used to control growth along the surface or within the window regions 108.

### Experimental Results

As an example, 0.2˜2 μm non-polar m-plane GaN film is deposited on m-plane SiC substrate using an AlN nucleation layer by MOCVD to form a template. This template should be smooth and crack-free enough to get flat sidewalls after SLEO processing. From our experience, thick m-plane GaN might have striated or slate morphology and this affects to coalescence. However, thin template might cause poor initiation or lateral growth on sidewalls. Optimized thickness for template and SLEO is preferred. Alternatively, this template can be deposited by MBE. A 200-2000 A thick SiO₂ film is deposited on this template by plasma-enhanced chemical vapor deposition (PECVD). The parallel stripe mask pattern oriented along the<112-0> direction is transferred to the SiO₂ film using conventional photolithographic techniques. On this experiment, 8 μm-wide stripes separated by 2 μm-wide openings are used. Using PR mask, SiO₂, GaN and AIN in the opening regions are dry etched down to the substrate and this etching process can be replaced by wet etching using HCl and HF. Because After patterning the mask, the sample was solvent cleaned to remove PR, and loaded for selective epitaxy regrowth using MOCVD.

During this lateral/vertical regrowth (step (e) in FIG. 1), low pressure (70 torr) and pretty low V/III ratio (354) at high temperature (1180 C) are used. With this growth condition, initiation on the sidewalls of exposed GaN is begun, and starts growing laterally and vertically. Because of characteristic of this growth direction, defects are already reduced except edges of window regions where GaN meets mask materials. Also, due to Ga-face on (0001) c-plane GaN has a faster growth rate than N-face on (0001-) c-plane GaN, unique shape of regrown GaN is formed. To get fully coalesced on the top side of regrown GaN, fast growth rate is preferred by MOCVD or HVPE. In this experimentation, HVPE is used for full-coalescence after MOCVD coalesces partially with fast growth rate (2×).

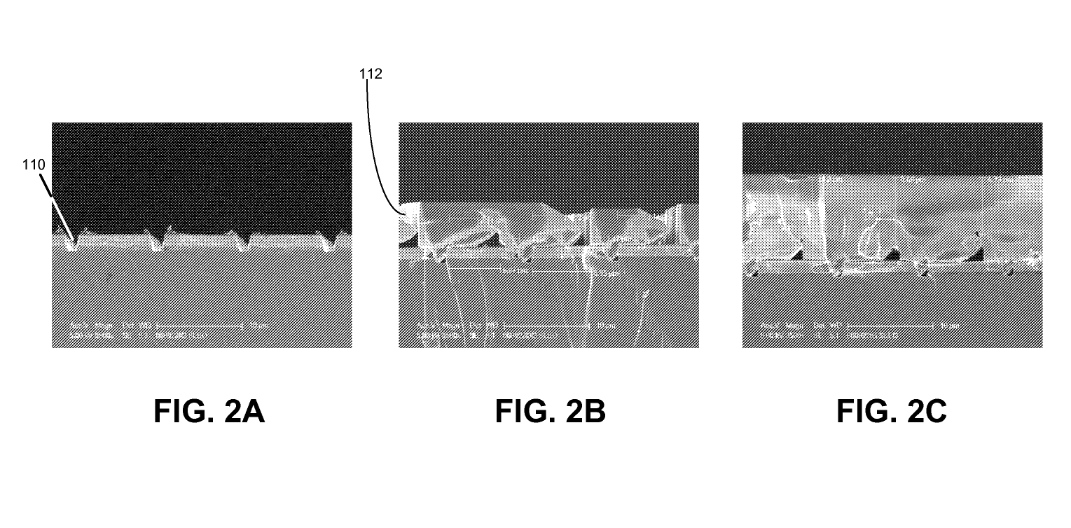

FIG. 2(a) is a scanning electron microscopy image of patterned SLEO template prepared by MBE template and processed by photolithography with 2/8 mask. FIG. 2(a) shows the substrate and layers as described in step (d) of FIG. 1. The initial template can be grown by either MOCVD or MBE. During photolithography process, etching down to the substrate with flat sidewalls of GaN is essential.

FIG. 2(b) is a SEM image of step (e) of FIG. 1, which shows there is lateral and vertical growth of layer 112 (the non-polar m-plane GaN material), and some regions are already coalesced (have reached intersections 120) after this step is done, as shown in step (e) of FIG. 1. FIG. 2(c) is a SEM image showing tops of overgrown layer is fully coalesced by double the growth rate by MOCVD only. This is a SEM of step (f) of FIG. 1.

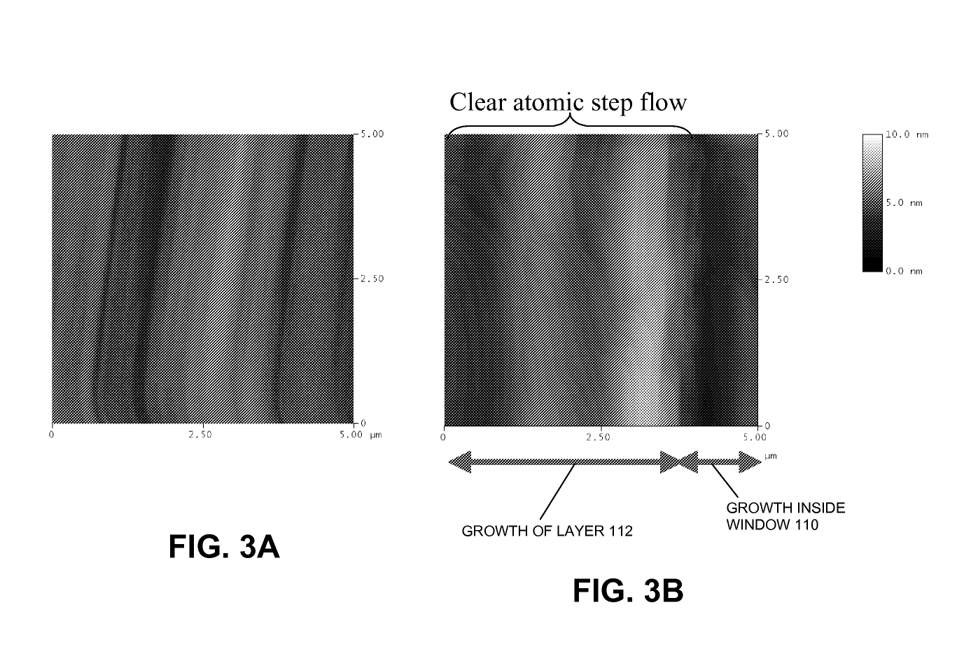

FIG. 3(a) and 3(b) are Atomic Force Microscopy (AFM) images.

FIG. 3(a) shows an AFM for a planar template, where m-plane GaN is grown directly on an m-plane SiC substrate. The Root Mean Square (RMS) roughness of the planar template, e.g., the roughness of the GaN layer, is 13.8 nm. FIG. 3(b) shows an AFM of a SLEO template, where the RMS roughness is decreased to 1.15 nm at the upper surface (the top of layer 112 in step (f) of FIG. 1). The decrease in roughness in the SLEO-grown m-plane GaN is because defects are reduced in the SLEO grown material (layer 112), where slate or striated morphology is common in the planar-grown GaN. The “wing” region is layer 112 above surface 114, whereas “window” region is the portion of layer 112 that is grown within the windows 108. Typically, after the layer 112 is grown, the template layer 104, and thus, the upper surface of layer 112, show dislocation densities of less than 10⁹ cm⁻² and stacking fault densities of less than 10⁵ cm⁻¹.

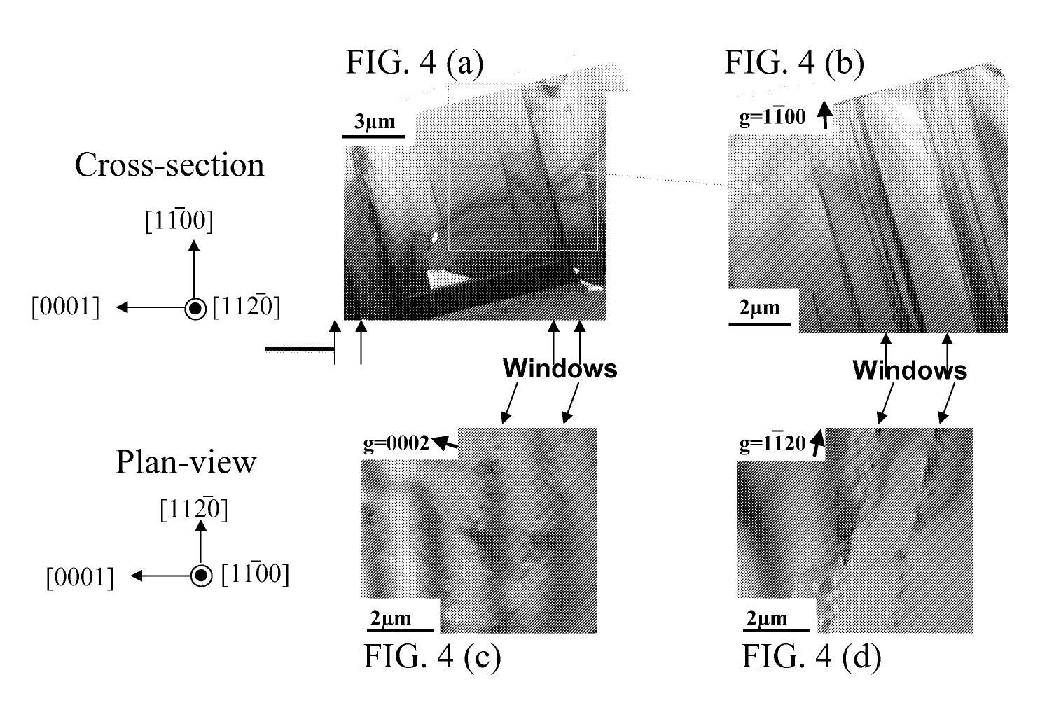

FIG. 4(a), 4(b), 4(c), and 4(d) are transmission electron microscopy images.

FIG. 4(a) is the cross section image of fully coalesced SLEO template (layer 112) and FIG. 4(b) is enlarged from the rectangular region of FIG. 4(a) for showing localized stacking faults. FIGS. 4(c) and 4(d) are plane-view images to show dislocation densities. In FIGS. 4(a) and 4(b), stacking faults (dark lines) are disappeared except at the edges of windows 108. In FIGS. 4(c) and 4(d), dislocations are also shown only at the edges of window regions 108.

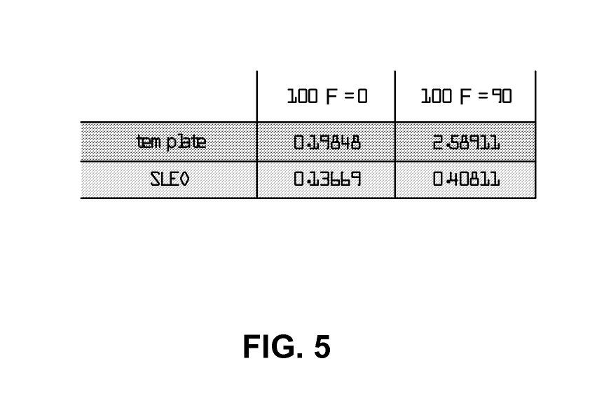

FIG. 5 is a table for x-ray diffraction full width half maximum values scanned on-axis for planar template and fully coalesced SLEO template. All FWHM values are decreased when SLEO structure is applied to m-plane GaN. This means quality of film has been increased because defects are reduced.

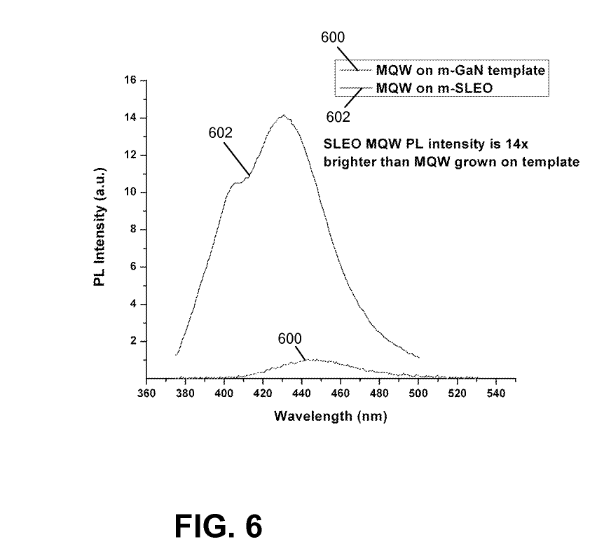

FIGS. 6 is the Photoluminescence measurement result for planar template and fully coalesced SLEO template. PL intensity is increased by 14 times with SLEO because defects are reduce and band-edge emission is stronger. Line 600 shows the photoluminescence of a Multiple Quantum Well (MQW) structure grown directly on an m-GaN template, whereas line 602 shows the MQW structure grown on an m-plane SLEO substrate in accordance with the present invention.

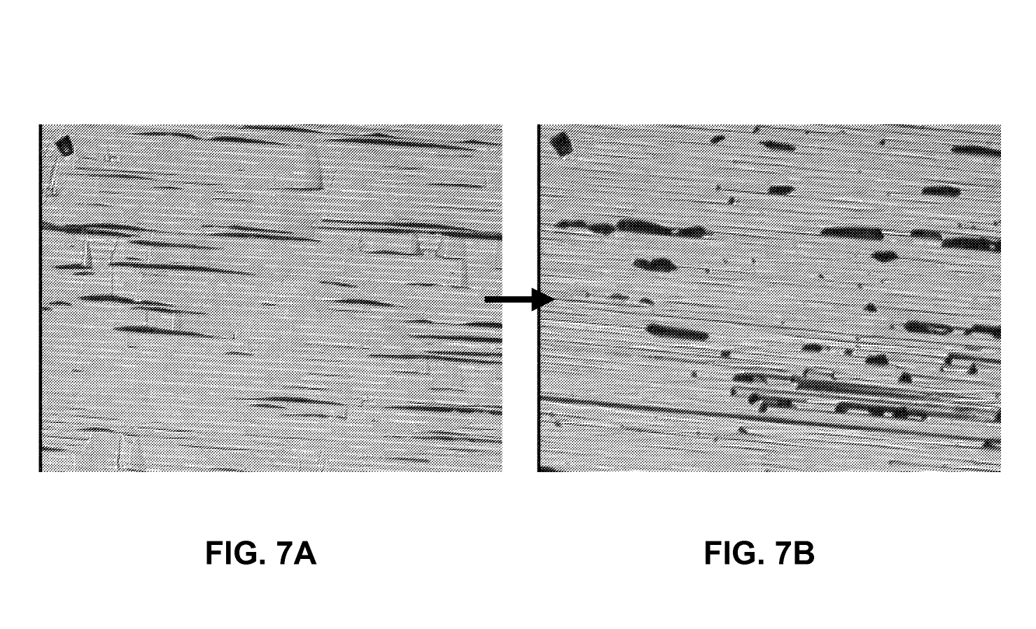

FIGS. 7(a) and 7(b) are the optical microscopy images for showing surface smoothing process.

FIG. 7(a) is an example of a rough surface right after coalescence is done by MOCVD or HVPE, and FIG. 7(b) is an example of when surface smoothing is completed on layer 112. Surface smoothing is achieved by further MOCVD growth using the growth conditions previously described for layer 112. Smoothing of the surface occurs by growing layer 112 for additional time whether MOCVD or HVPE, or other growth techniques. Additional growth time of layer 112 allows for better surface quality and thus better device quality and yields.

### Possible Modifications and Variations

The preferred embodiment has described a lateral epitaxial overgrowth process from the etched sidewalls of a non-polar m-plane GaN template. Coalescence or surface smoothness can be affected by miscut orientation of substrate. Initial template or coalescing can be done by MOCVD, HVPE, or MBE.

The preferred embodiment has described a LEO process from the etched sidewalls of a non-polar or semi-polar III-Nitride template. Alternative appropriate substrate materials, on which the non-polar or semi-polar III-Nitride or GaN template could be formed include but are not limited to a- and m-plane SiC or r-plane Al₂O₃. The template material to use as a base for the sidewall growth process can be any non-polar or semi-polar III-Nitride template material including but not limited to GaN, AlN, AlGaN, and InGaN with various thicknesses and crystallographic orientations. This material can be formed by any means using MOCVD or HVPE or any other variety of methods. To grow such template material different nucleation layers including GaN and AlN can be used. A variety of mask materials, including dielectric, and geometries with various aperture or opening spacing, sizes and dimensions may be used. Mask deposition methods with different mask thicknesses, and mask patterning technique with various orientations may be used in practice of this invention without significantly altering the results. Many alternative etching methods, including but not limited to wet and dry etching techniques, can be used while etching the mask and/or the template material. The etch depth of the template material can be varied as long as the material growing laterally from the sidewalls coalesces and blocks the defective material growing vertically from the trench bottoms. Etching of the substrate can be included in the process to ensure growth only from the sidewalls. The one or more trenches formed by the etching may have a variety of shapes, comprising U shaped or V shaped grooves, holes or pits.

Another possible variation could be that after etching the III-Nitride material as described above, an additional mask may be deposited on the bottom of the trenches to allow regrowth from the sidewalls only. The growth parameters required for the lateral overgrowth of non-polar or semi-polar III-Nitride from the sidewalls will vary from reactor to reactor. Such variations do not fundamentally alter the general practice of this invention. Although it is desirable, final coalescence of the film over the mask is not a requirement for the practice of this invention. Therefore, this disclosure applies to both coalesced and uncoalesced laterally overgrown non-polar or semi-polar III-Nitride films from sidewalls.

The invention described herein, and all its possible modifications, can be applied multiple times by repeating the SLEO process after achieving coalescence, one layer over another layer, thereby creating a multi-step SLEO process to decrease defect densities even further. This invention can be practiced with any kind of growth method including but not limited to metalorganic chemical vapor deposition (MOCVD), and Hydride Vapor Phase Epitaxy (HVPE), and molecular beam epitaxy (MBE), or the combination of any of these growth methods at various stages of SLEO processing and growth.

### Advantages and Improvements

The present invention is a successful execution of SLEO of m-plane non-polar GaN. It is now possible to reduce the presence of dislocations most effectively in the simplest possible way in non-polar or semi-polar III-Nitride materials, while preventing polarization effects in the resulting devices.

A previous report similar to sidewall lateral overgrowth (SLEO) of GaN by MOCVD is known as pendeo-epitaxy. This technique has been demonstrated only for polar c-plane GaN growth. And, it also has fundamental differences in terms of processing and growth. For example, the substrate, relatively expensive SiC, is used as a “pseudo” mask, meaning that the growth takes place selectively only at the sidewalls and not on the substrate. As a result, the material has to be etched down to the substrate and also the etching process should be continued into the substrate until a certain depth. Consequently, the growth does not initiate through open windows. Therefore, there is no variable involved during growth to coalesce tops of the sidewalls through the open windows before the vertically grown material from the bottom of the trenches reaches the tops of the sidewalls. The lateral growth involves the nucleation on and growth from the whole etched sidewall. The main focus is the growth of the whole pillar.

Another similar study, lateral overgrowth from trenches (LOFT), suggested growing GaN from the trenches by only exposing the sidewalls after depositing SiO₂ mask to the top and the bottom of the pillars. This was demonstrated only for polar c-GaN.

Presently, GaN films must be grown heteroepitaxially due to the unavailability of bulk crystals, and no perfectly lattice-matched substrates exist for this growth process. As a result, the present invention also produces an excellent material base to grow free standing GaN substrate for eventual homoepitaxial growth.

### REFERENCES

The following references are incorporated by reference herein:

1. Tsvetanka S. Zhelva, Scott A. Smith, et al., “Pendeo-Epitaxy—A new approach for lateral growth GaN structures,” MRS Internet J. Nitride Semicond. Res. 4S1, G3.38 (1999).

2. Y. Chen, R. Schneider, Y. Wang, “Dislocation reduction in GaN thin films via lateral overgrowth from trenches”, Appl. Phys. Letters., 75 (14) 2062 (1999).

3. Kevin Linthicum, Thomas Gehrke, Darren Thomson, et al., “Pendeoepitaxy of gallium nitride films,” Appl. Phys. Lett., 75 (2) 196 (1999).

4. M. D. Craven, S. H. Lim, F. Wu, J. S. Speck, and S. P. DenBaars, “Threading dislocation reduction via laterally overgrown nonpolar (11-20) a-plane GaN,” Appl. Phys. Lett., 81 (7) 1201 (2002).

5. Changqing Chen, Jianping Zhang, Jinwei Yang, et al., “A new selective area lateral epitaxy approach for depositing a-plane GaN over r-plane sapphire,” Jpn. J. Appl. Phys. Vol. 42 (2003) pp. L818-820.

### CONCLUSION

This concludes the description of the preferred embodiment of the present invention.

The present invention comprises methods and devices for reducing threading dislocation densities in a III-nitride material. Such a method comprises growing a nucleation layer on a substrate, growing a template layer on the nucleation layer, the template layer providing a crystal orientation, depositing a mask on the template layer, the mask having a top surface, etching the mask, the template layer, and the nucleation layer, wherein the crystal orientation is exposed on the template layer in a plurality of windows created by the etching, growing a group-III nitride layer within the plurality of windows, wherein when the growth of the group-III nitride layer reaches the top surface, the group-III nitride layer grows along the top surface such that growth within a first window coalesces with growth of a second window at an intersection point to create a substantially planar upper surface of the group-III nitride layer, and smoothing the substantially planar upper surface of the group-III nitride layer, such that the group-III nitride layer has a reduced number of threading dislocation densities.

Such a method further optionally comprises the substantially planar upper surface of the group-III nitride layer being in an m-plane,the group-III nitride layer being a non-polar material, the group-III nitride layer growing laterally along the top surface of the mask blocking the group-III nitride material growing vertically from the windows, the windows being aligned to create planar sidewalls in subsequent lateral growth steps, the template layer having a thickness scaled relative to a size of the windows to compensate for competing lateral to vertical growth rates, the etching being performed to one or more etch depths in order for the group-III nitride layer growing along the top surface to coalesce before the group-III nitride material growing within the windows completely reaches the tops of the sidewalls, changing a growth method of the group-III nitride layer after coalescence, the group-III nitride layer being grown in a temperature range of 1000-1250 ° C. and in a reactor pressure in a range of 20-760 Torr, the group-III nitride layer having a V/III ratio in a range of 100-3500 during different stages of the growth, and wherein a lateral growth rate is greater than a vertical growth rate, preventing growth from the bottoms of the trenches by depositing an additional mask on the bottoms of the trenches, and a device made by the method.

The method further optionally comprises a Root Mean Square (RMS) roughness of the upper surface of the group-III nitride layer is less than 13.8 nm, an overall area of the template layer has dislocation densities of less than 10⁹ cm⁻² and stacking fault densities of less than 10⁵ cm⁻¹, and devices made using the method wherein the device is an optoelectronic device, and the group-III nitride layer is either a non-polar group-III nitride layer or a semi-polar group-III nitride layer.

The foregoing description of one or more embodiments of the invention has been presented for the purposes of illustration and description. It is not intended to be exhaustive or to limit the invention to the precise form disclosed. Many modifications and variations are possible in light of the above teaching, such as additional adjustments to the process described herein, without fundamentally deviating from the essence of the present invention. It is intended that the scope of the invention be limited not by this detailed description, but rather by the claims appended hereto.

What is claimed is:

1. A method of reducing threading dislocation densities in a III-Nitride material, comprising:
growing a nucleation layer on a substrate;
growing a template layer on the nucleation layer, the template layer providing a crystal orientation;
depositing a mask on the template layer, the mask having a top surface;
etching the mask, the template layer, and the nucleation layer, wherein the crystal orientation is exposed on the template layer in a plurality of windows created by the etching;
growing a group-III nitride layer within the plurality of windows, wherein when the growth of the group-III nitride layer reaches the top surface, the group-III nitride layer grows along the top surface such that growth within a first window coalesces with growth of a second window at an intersection point to create a substantially planar upper surface of the group-III nitride layer; and
smoothing the substantially planar upper surface of the group-III nitride layer, such that the group-III nitride layer has a reduced number of threading dislocation densities.

2. The method of claim 1, wherein the substantially planar upper surface of the group-III nitride layer is in an m-plane.

3. The method of claim 2, wherein the group-III nitride layer is a non-polar material.

4. The method of claim 3, wherein the group-III nitride layer growing laterally along the top surface of the mask blocks the group-III nitride material growing vertically from the windows.

5. The method of claim 3, wherein the windows are aligned to create planar sidewalls in subsequent lateral growth steps.

6. The method of claim 3, wherein the template layer has a thickness scaled relative to a size of the windows to compensate for competing lateral to vertical growth rates.

7. The method of claim 6, wherein the etching is performed to one or more etch depths in order for the group-III nitride layer growing along the top surface to coalesce before the group-III nitride material growing within the windows completely reaches the tops of the sidewalls.

8. The method of claim 7, further comprising changing a growth method of the group-III nitride layer after coalescence.

9. The method of claim 3, wherein the group-III nitride layer is grown in a temperature range of 1000-1250 ° C. and in a reactor pressure in a range of 20-760 Torr.

10. The method of claim 9, wherein the group-III nitride layer has a V/III ratio in a range of 100-3500 during different stages of the growth, and wherein a lateral growth rate is greater than a vertical growth rate.

11. The method of claim 3, further comprising:
preventing growth from the bottoms of the trenches by depositing an additional mask on the bottoms of the trenches.

12. A device made using the method of claim 1.

13. The method of claim 1, wherein a Root Mean Square (RMS) roughness of the upper surface of the group-III nitride layer is less than 13.8 nm.

14. The method of claim 1, wherein an overall area of the template layer has dislocation densities of less than 10⁹ cm⁻² and stacking fault densities of less than 10⁵ cm⁻¹.

15. The method of claim 2, wherein the group-III nitride layer is a non-polar material.
